(19) United States
(12) Patent Application Publication
(10) Pub. No.: US 2012/0327572 A1
(43) Pub. Date: Dec. 27, 2012

(54) PORTABLE ELECTRONIC DEVICE WITH COVERS HAVING HIDDEN DETENTS

(75) Inventors: KE-HUI PENG, Shenzhen City (CN); XUE-DONG TANG, Shenzhen City (CN); LI-NI LIANG, Shenzhen City (CN); REN-WEN WANG, Shenzhen City (CN)

(73) Assignees: HON HAI PRECISION INDUSTRY CO., LTD., New Taipei (TW); HONG FU JIN PRECISION INDUSTRY (ShenZhen) CO., LTD., Shenzhen City (CN)

(21) Appl. No.: 13/241,275

(22) Filed: Sep. 23, 2011

(30) Foreign Application Priority Data
Jun. 24, 2011 (CN) 201110173064.8

(51) Int. Cl. H05K 5/03

(52) U.S. Cl. 361/679.01

(57) ABSTRACT

An exemplary portable electronic device includes a bottom cover and a top cover engaging with the bottom cover. Recesses are defined in the bottom cover. Strips are protruded down from the top cover and corresponding to the recesses of the bottom cover. The strips of the top cover fittedly engage in the recesses of the bottom cover to assemble the bottom cover and the top cover together. The assembled bottom cover and top cover cooperatively form a shell, and the strips and the recesses are located at an inside of the shell.

### BACKGROUND

1. Technical Field

The present disclosure relates to portable electronic devices, and particularly to a portable electronic device having two interengaging covers.

2. Description of Related Art

Generally, a portable electronic device includes a shell housing a plurality of electronic components therein. The shell includes a top cover and a bottom cover. Strips respectively protrude from opposite sides of the top cover. The strips engage into slots of the bottom cover to assemble the bottom cover and the top cover together. However, the top cover and the bottom cover are generally made by plastic injection molding. Typically, a color of parts of the top cover near the strips is different from that of other parts of the top cover, and a color of parts of the bottom cover near the slots is different from that of other parts of the bottom cover. Thus, chromatic aberration of the shell is produced, and the aesthetic appearance of the shell is affected.

What is needed, therefore, is a shell of a portable electronic device which can overcome the described limitations.

### BRIEF DESCRIPTION OF THE DRAWINGS

FIG. 1 is a schematic, isometric assembled view of a portable electronic device according to an embodiment of the present disclosure.

FIG. 2 is an enlarged, cutaway view of part of a shell of the portable electronic device of FIG. 1.

FIG. 3 is a disassembled view of the part of the shell of FIG. 2.

FIG. 4 is essentially a disassembled view of the part of the shell of FIG. 2 when the part of the shell is inverted.

FIG. 5 is essentially a plan view of the part of the shell shown in FIG. 2.

### DETAILED DESCRIPTION

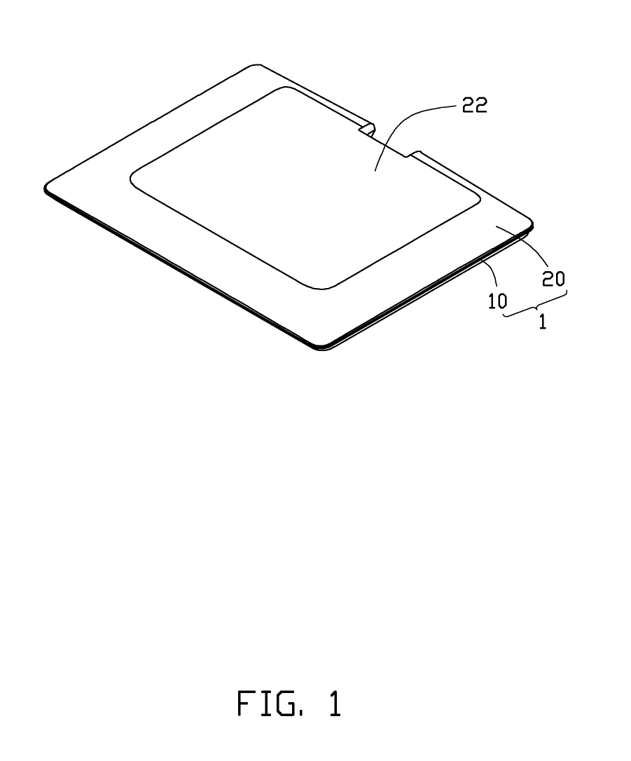

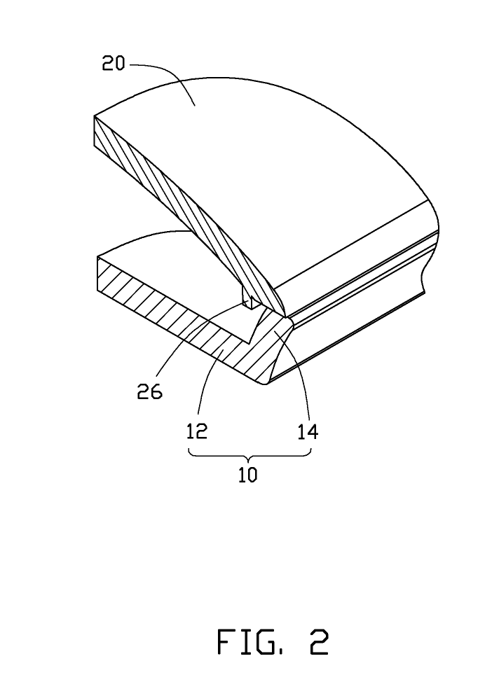

Referring to FIGS. 1-2, a portable electronic device (not labeled) is shown. The portable electronic device includes a shell 1 and a lid 22 engaging with the shell 1. The shell 1 houses a plurality of electronic components (not shown) therein, and includes a top cover 20 and a bottom cover 10 engaging with the top cover 20. The top cover 20 and the bottom cover 10 are plastic and made by plastic injection molding. The lid 22 is mounted on the top cover 20 and rotatable up and down relative to the shell 1, so that a working space (not shown) of the portable electronic device is covered by the lid 22 or is exposed.

The bottom cover 10 includes a substantially rectangular bottom plate 12, and two sidewalls 14 extending up from opposite sides of the bottom plate 12 to the top cover 20. The bottom plate 12 and the sidewalls 14 cooperatively define a receiving chamber 15 therebetween to receive the electronic components therein.

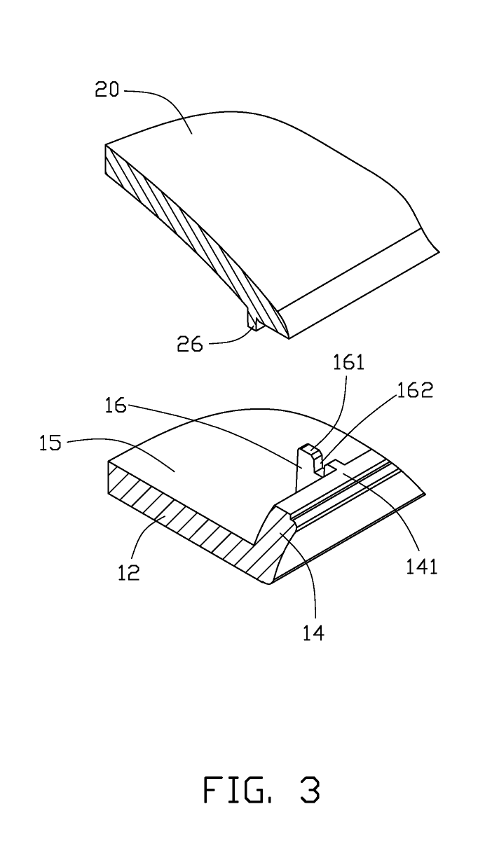

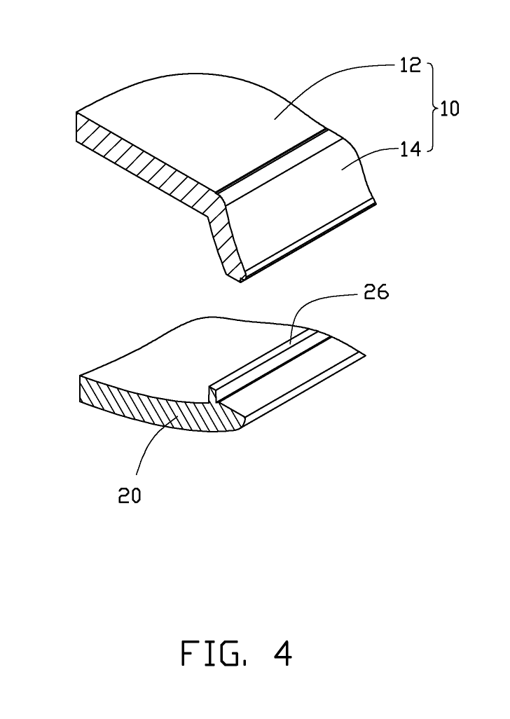

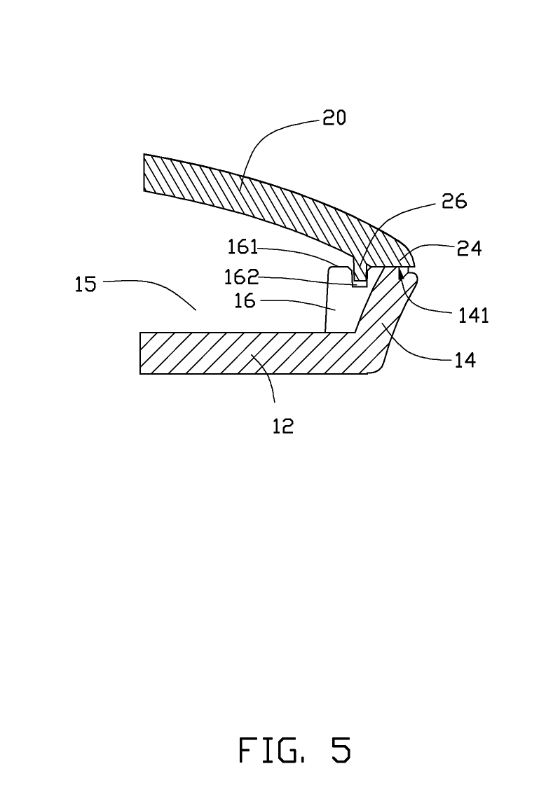

Referring also to FIGS. 3-5, only a part of one of the sidewalls 14 is shown. The sidewall 14 abuts against the top cover 10. A rib 16 protrudes from the bottom plate 12 to engage with the top cover 20. A lateral side of the rib 16 connects an inner surface of the sidewall 14. A top surface 161 of the rib 16 is planar, and coplanar with a top surface 141 of the sidewall 14. A recess 162 is defined in a middle portion of a top end of the rib 16. Understandably, another rib 16 (not shown) is formed on the bottom plate 14 adjacent to the other sidewall 14. Alternatively, there can be a plurality of ribs 16 formed on each of the opposite sides of the bottom plate 12 and respectively connecting the two sidewalls 14.

The top cover 20 is gently arc-shaped in cross-section, and has two elongated strips 26 protruding from opposite sides of a bottom surface thereof (only one of the strips 26 is shown in FIGS. 2-5). The strips 26 protrude toward the recesses 162 of the ribs 16 of the bottom cover 10. Flanges 24 are respectively formed at the opposite sides of the cover 20, and are respectively located at outer sides of the strips 26. A bottom surface of each flange 24 is planar, and abuts against the top surface 141 of the sidewall 14 of the bottom cover 10 when the shell 1 is assembled. A length of each strip 26 is much larger than a corresponding length of the respective recess 162. Therefore when there is a plurality of the ribs 16 formed on each of the opposite sides of the bottom plate 12, each strip 26 can engage in the recesses 162 of the corresponding plurality of ribs 16.

In assembly, the strips 26 of the top cover 20 fittedly engage in the recesses 162 of the bottom cover 10 to assemble the top cover 20 and the bottom cover 10 together. Thus, the shell 1 is assembled. In this state, the flanges 24 of the top cover 20 abut against the top surfaces 141 of the sidewalls 14 of the bottom cover 10. The strips 26 engaged in the recesses 162 are received in the receiving chamber 15 of the bottom cover 10.

In this embodiment, the ribs 16 and the strips 26 are inside the shell 1. Therefore even if the color of parts of the top cover 20 near the strips 26 is different from that of other parts of the top cover 20, and/or even if the color of parts of the bottom cover 10 near the recess(es) 162 is different from that of other parts of the bottom cover 10, any chromatic aberration produced is not visible to a user. Accordingly, the aesthetic appearance of the shell 1 can be improved.

It is to be understood, however, that even though numerous characteristics and advantages of the embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A portable electronic device comprising:
a bottom cover, a plurality of recesses defined in the bottom cover; and
a top cover, a plurality of strips protruding down from the top cover and corresponding to the recesses of the bottom cover;
wherein the strips of the top cover fittedly engage in the recesses of the bottom cover to assemble the bottom cover and the top cover together, the assembled bottom cover and top cover cooperatively form a shell, and the strips and the recesses are inside the shell.

2. The portable electronic device of claim 1, wherein the bottom cover comprises a bottom plate and two sidewalls extending up from opposite sides of the bottom plate, and top ends of the sidewalls abut against the top cover.

3. The portable electronic device of claim 2, wherein a plurality of ribs is formed on the bottom plate of the bottom cover, each rib defines a corresponding one of the recesses therein, and the ribs are inside the shell.

4. The portable electronic device of claim 3, wherein the ribs are located at the opposite sides of the bottom plate, and lateral sides of the ribs respectively connect the sidewalls.

5. The portable electronic device of claim 4, wherein each of the recesses is defined at a middle portion of a top end of the corresponding rib.

6. The portable electronic device of claim 4, wherein the top ends of the sidewalls and top ends of the ribs are coplanar.

7. The portable electronic device of claim 2, wherein two flanges are respectively formed at the opposite sides of the top cover and are located at outer sides of the strips, respectively, and bottom surfaces of the flanges abut against the top ends of the sidewalls.

8. The portable electronic device of claim 1, further comprising a lid engaged with the top cover and rotatable up and down relative to the top cover.

9. The portable electronic device of claim 1, wherein a length of each of the strips is larger than a corresponding length of the respective recess.

10. A portable electronic device comprising:
a bottom cover, the bottom cover comprising a bottom plate and two sidewalls extending up from opposite sides of the bottom plate, a plurality of ribs formed on the opposite sides of the bottom plate, and each rib defining a recess in a top thereof; and
a top cover, a plurality of strips protruding down from the top cover and corresponding to the recesses of the ribs of the bottom cover;
wherein the strips of the top cover fittedly engage in the recesses of the bottom cover to assemble the bottom cover and the top cover together, with tops of the sidewalls abutting a bottom surface of the top cover, and the strips and the ribs located between the sidewalls.

11. The portable electronic device of claim 10, wherein the ribs respectively connect the sidewalls.

12. The portable electronic device of claim 10, wherein the recess is defined in a middle portion of a top end of the rib.

13. The portable electronic device of claim 10, wherein the top ends of the sidewalls and top ends of the ribs are coplanar.

14. The portable electronic device of claim 10, wherein two flanges are respectively formed at the opposite side of the top cover and respectively located at outer sides of the strips, and bottom surfaces of the flanges abut against the top ends of the sidewalls.

15. The portable electronic device of claim 10, wherein a lid engages with the top cover and is rotatable up and down relative to the top cover.

16. A portable electronic device comprising:
two covers coupled with each other to define a space therebetween for receiving electronic components, one of the two covers defining at least one recess, the at least one recess in communication with the space, and the other one of the two covers comprising at least one strip extending into the space, the at least one strip being engaged in the at least one recess.

17. The portable electronic device of claim 16, wherein a rib extends from the one of the two covers towards the other one of the two covers, the at least one recess being defined in the rib.

18. The portable electronic device of claim 16, wherein two flanges extend outwardly from opposite sides of one of the two covers and abut the other cover, and the at least one strip is located between the two flanges.

19. The portable electronic device of claim 16, further comprising a lid rotatably engaged with the cover that comprises the at least one strip.
